(19) United States
(12) Patent Application Publication
(10) Pub. No.: US 2026/0305291 A1
(43) Pub. Date: Oct. 1, 2026

(54) INCREASED THERMAL CONDUCTIVITY OF SEMI-DAMASCENE METAL WIRING

(71) Applicant: International Business Machines Corporation, Armonk, NY (US)

(72) Inventors: Kevin Wayne Brew, Niskayuna, NY (US); Darsith Jayachandran, Menands, NY (US); Christopher J. Penny, Saratoga Springs, NY (US); Prabudhya Roy Chowdhury, Albany, NY (US); Koichi Motoyama, Clifton Park, NY (US)

(21) Appl. No.: 19/089,120

(22) Filed: Mar. 25, 2025

(51) Int. Cl. H01L 23/522; H01L 21/768; H01L 23/532

(52) U.S. Cl. CPC H10W 20/42; H10W 20/056; H10W 20/063; H10W 20/072; H10W 20/081; H10W 20/4441; H10W 20/46; H10W 20/48

(57) ABSTRACT

A semiconductor interconnect structure and formation thereof. The semiconductor interconnect structure includes: a set of lower-level metal lines, the set of lower-level metal lines formed by subtractive etching; a thermal conductive layer formed above the set of lower-level metal lines; an interlayer dielectric layer surrounding sidewalls of the set of lower-level metal lines and the thermal conductive layer formed above the set of lower-level metal lines; a via formed above a first metal line in the set of lower-level metal lines; and a set of upper-level metal lines formed above the thermal conductive layer, where a thermal conductivity of the thermal conductive layer is greater than a thermal conductivity of the interlayer dielectric layer.

### BACKGROUND

The present disclosure generally relates to fabrication methods and resulting structures for semiconductor devices, and more specifically, to fabrication methods and resulting structures for semi-damascene interconnect structures having increased thermal conductivity.

For an integrated circuit (IC) device to be functional, multi-level or multi-layered interconnection schemes such as, for example, metal wiring formed by additive manufacturing processes (e.g., single damascene processes or dual damascene processes), subtractive manufacturing processes (e.g., subtractive etching processes), and combinations thereof, are fabricated in the back-end-of-line (BEOL) of the device to connect the circuit elements distributed in the front-end-of-line (FEOL) of the device. Connections between the metal wiring of the different interconnect levels, called vias, allow signals and power to be transmitted between one level to the next.

### SUMMARY

According to one embodiment of the present invention, a semiconductor interconnect structure is provided. The semiconductor interconnect structure includes: a set of lower-level metal lines, the set of lower-level metal lines formed by subtractive etching; a thermal conductive layer formed above the set of lower-level metal lines; an interlayer dielectric layer surrounding sidewalls of the set of lower-level metal lines and the thermal conductive layer formed above the set of lower-level metal lines; a via formed above a first metal line in the set of lower-level metal lines; and a set of upper-level metal lines formed above the thermal conductive layer, where a thermal conductivity of the thermal conductive layer is greater than a thermal conductivity of the interlayer dielectric layer.

According to another embodiment of the present invention, a method of forming a semiconductor interconnect structure is provided. The method includes: forming a set of lower-level metal lines, the set of lower-level metal lines formed by subtractive etching; forming a thermal conductive layer above the set of lower-level metal lines; forming an interlayer dielectric layer, the interlayer dielectric layer surrounding sidewalls of the set of lower-level metal lines and the thermal conductive layer formed above the set of lower-level metal lines; forming a via above a first metal line in the set of lower-level metal lines; and forming a set of upper-level metal lines above the thermal conductive layer, where a thermal conductivity of the thermal conductive layer is greater than a thermal conductivity of the interlayer dielectric layer.

### BRIEF DESCRIPTION OF THE SEVERAL VIEWS OF THE DRAWINGS

The drawings included in the present application are incorporated into, and form part of, the specification. They illustrate embodiments of the present invention and, along with the description, explain the principles of the invention. The drawings are only illustrative of certain embodiments and do not limit the invention.

FIG. 1 illustrates a cross-sectional view of a semiconductor interconnect structure 100 at an intermediate step during a semiconductor manufacturing process, in accordance with at least one embodiment of the present invention.

FIG. 2 illustrates a cross-sectional view of semiconductor interconnect structure 100 of FIG. 1 after performing subsequent processing steps, in accordance with at least one embodiment of the present invention.

FIG. 3 illustrates a cross-sectional view of semiconductor interconnect structure 100 of FIG. 2 after performing subsequent processing steps, in accordance with at least one embodiment of the present invention.

FIG. 4 illustrates a cross-sectional view of semiconductor interconnect structure 100 of FIG. 3 after performing subsequent processing steps, in accordance with at least one embodiment of the present invention.

FIG. 5 illustrates a cross-sectional view of semiconductor interconnect structure 100 of FIG. 4 after performing subsequent processing steps, in accordance with at least one embodiment of the present invention.

FIG. 6 illustrates a cross-sectional view of semiconductor interconnect structure 100 of FIG. 5 after performing subsequent processing steps, in accordance with at least one embodiment of the present invention.

### DETAILED DESCRIPTION

The present disclosure generally relates to fabrication methods and resulting structures for semiconductor devices, and more specifically, to fabrication methods and resulting structures for semi-damascene interconnect structures having increased thermal conductivity.

In conventional interconnect schemes, connections between the metal lines of the different interconnect levels, called vias, allow signals and power to be transmitted between one level to the next. When fabricating integrated circuit wirings within a multi-layered scheme, an insulating or dielectric material (e.g., silicon oxide or a low-κ insulator) will normally be patterned with several thousand openings to create conductive line openings and/or via openings using single or dual damascene processes. The line openings and via openings are typically filled with a conductive metal material (e.g., copper, aluminum, etc.) to electrically interconnect the active and/or passive elements of the integrated circuits.

For decades, state-of-the-art interconnects were formed from the subtractive patterning of aluminum. In the late 1990's, as integrated circuits (ICs) moved to smaller technology nodes, a shift from aluminum-based interconnects to copper-based interconnects formed from a dual-damascene process occurred due to the increasing resistor-capacitor (RC) delay in aluminum-based interconnects. In addition to the fact that copper dual-damascene is more cost-effective than aluminum and is applicable to multiple interconnect levels of the back-end-of-line (BEOL), copper wires conduct electricity with about 40% less resistance than aluminum wires, which translates to about a 15% increase in processing speed.

However, as the size of ICs have reached 2 nanometers and beyond, we are now approaching the physical limits of what we can do with copper wiring. This stems from the fact that as the pitch of the copper metal lines approach copper's electron mean free path, the RC delay will increase significantly. Additionally, copper interconnects have always required a barrier, liner, and cap layers to ensure good device reliability and prevent copper from diffusing into the surrounding dielectric. But these additional layers, which take up valuable space, have become a hinderance to the development of smaller ICs. This, in turn, has led to the recent development of interconnect formation using a semi-damascene process.

Typically, the semi-damascene process begins with the subtractive patterning (e.g., subtractive etching) of a first metal layer to form a first interconnect level of the BEOL and thus requires a suitable patternable material such as molybdenum (Mo), ruthenium (Ru), or tungsten (W). The via that connects with the next interconnect level is then patterned using a single-damascene process, in which the dielectric above the first interconnect layer is etched and filled with metal and overfilled (i.e., the deposition of the metal continues until a second layer of metal is formed on top of the dielectric). Then, subtractive patterning of the second metal layer formed on top of the dielectric is performed to form a second interconnect level, with the metal lines of the second interconnect level being orthogonal to the metal lines of the first interconnect level.

With semi-damascene interconnect formation, the subtractive etching of high refractory metals allows for higher interconnect aspect ratios (ARs) than conventional copper (Cu) interconnects, improving the resistance. Furthermore, the use of high refractory metals that are patternable reduces the need for additional barrier, liner, and cap layers, which helps save on space. Moreover, the semi-damascene process allows for the potential formation of air gaps embedded between the metal lines instead of low-k dielectric gap fill. The embedded air gaps offer a lower dielectric constant than the dielectric material, which results in reduced interconnect parasitic capacitance.

Although these air-gap features are sought after for their extremely low dielectric constant, embodiments of the present invention recognize that heat does not travel well through the air gaps. This can be especially problematic in the lower-level BEOL interconnect layers which already pose a challenge to heat flux. In addition to the air gaps formed between the metal lines acting as a thermal insulator, embodiments of the present invention further recognize additional challenges to heat dissipation in the lower-level BEOL interconnect layers due to the low metal content in the via levels, coupled with the use of the lower thermally conductive refractory metals (e.g., molybdenum, molybdenum, tungsten) as compared to copper. For example, the thermal conductivity of ruthenium (~400 W/m/L) is roughly one-fourth the thermal conductivity of copper (116 W/m/K). Accordingly, embodiments of the present invention recognize the need to increase the thermal conductivity of BEOL wiring schemes that employ a semi-damascene process and/or the use of air gaps.

Embodiments of the present invention improve upon the foregoing deficiencies of conventional interconnect schemes by providing a method of forming a semi-damascene interconnect structure, and the semi-damascene interconnect structure formed as a result thereof, that increases the thermal conductivity of semi-damascene wiring structures, thereby creating a thermal path for heat transport in the regions between the different metal levels of the BEOL. This is accomplished by forming a thermal conductive layer with a high thermal conductivity within the via level above a set of lower-level metal lines.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this invention may be embodied in many different forms and should not be construed as limited to the exemplary embodiments set forth herein. Rather, these exemplary embodiments are provided so that this invention will be thorough and complete and will fully convey the scope of this invention to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” may mean that a first element can be etched, and the second element can act as an etch stop.

As used herein, terms such as “depositing,” “forming,” and the like may refer to the disposition of layers, or portions of materials, in accordance with a given embodiment. Such processes may or may not be different than those used in the standard practice of the art of semiconductor device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may also refer to processes that alter the structure and/or composition of one or more layers of material or portions of materials in accordance with a given embodiment. For example, such formation processes may include, but are not limited to, micromachining, microetching, wet and/or dry etching processes, plasma etching processes, or any of the known etching processes in which material is removed to form a particular structure.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

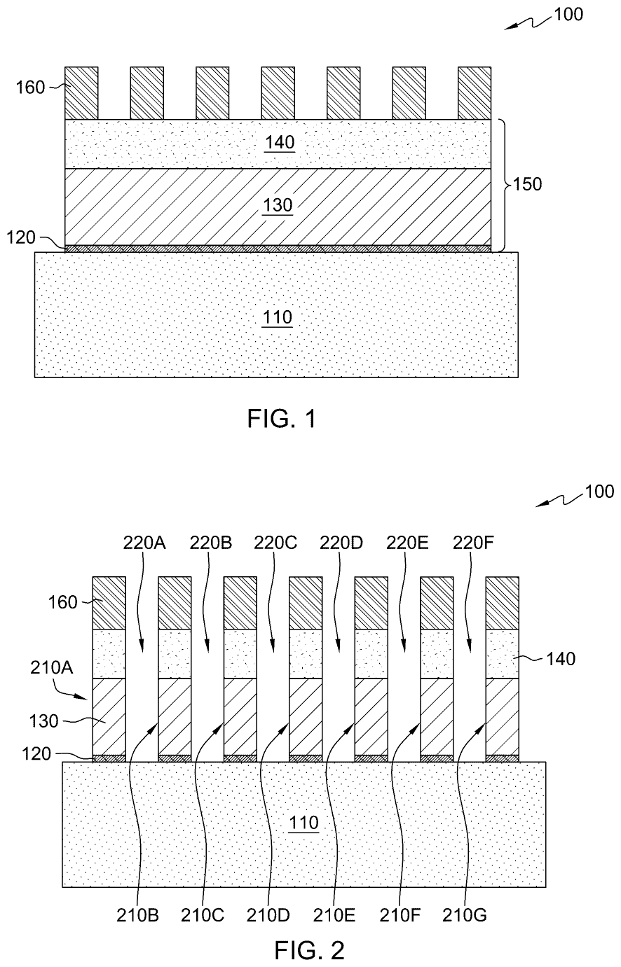

The present invention will now be described in detail with reference to the Figures, in which like numbers represent the same or similar elements. FIGS. 1-6 include various cross-sectional views depicting illustrative steps of methods for manufacturing semiconductor interconnect structures using a semi-damascene process, and the resulting semiconductor interconnect structures according to select embodiments of the present invention. One having ordinary skill in the art will appreciate that there are many options available for the formation of the structures described herein and that the following discussion does not limit embodiments to only the techniques described herein.

FIG. 1 depicts a cross-sectional view of a semiconductor interconnect structure 100 at an intermediate step during a semiconductor manufacturing process, in accordance with at least one embodiment of the present invention. In assembly of semiconductor interconnect structure 100 of FIG. 1, an initial material stack 150 is formed on a substrate 110, followed by the formation of a patterned mask 160 on top thereof. The material stack 150 includes, from bottom to top, an adhesion liner 120, a metal layer 130, and a thermal conductor layer 140. The material stack 150 may optionally include an etch stop layer (not depicted) formed on top of the thermal conductor layer 140.

In some embodiments, the substrate 110 may be a bulk-semiconductor substrate. In one example, the bulk-semiconductor substrate may be a silicon-containing material including, but not limited to, silicon, silicon germanium, silicon germanium carbide, silicon carbide, polysilicon, epitaxial silicon, amorphous silicon, or multi-layers thereof. Although silicon is the predominantly used semiconductor material in wafer fabrication, alternative semiconductor materials can be employed including, but not limited to, germanium, gallium arsenide, gallium nitride, cadmium telluride, zinc selenide, or multi-layers thereof. Although not depicted in the present figures, the substrate 110 may also be a semiconductor on insulator (SOI) substrate. In some embodiments, the substrate 110 may be an insulating material including, but not limited to, an organic insulator, an inorganic insulator, or multi-layers thereof. It should be appreciated that the substrate 110 may be comprised of any other suitable semiconductor material(s) than those listed above.

In some embodiments, the substrate 110 may include the front-end-of-line (FEOL). The FEOL is typically present beneath the lowest level of the multilayered interconnect structure and includes a semiconductor substrate having one or more semiconductor devices such as, for example, transistors, capacitors, resistors, and etc. located thereon. In some embodiments, substrate 110 may include one or more interconnect levels of a multilayered interconnect structure, such as the back-end-of-line (BEOL) and/or the middle-end-of line (MEOL). In such embodiments, each interconnect level may include one or more electrically conductive structures embedded in a dielectric material.

The material stack 150 may be formed by a multilayer deposition process using known deposition techniques including, but not limited to, chemical vapor deposition (CVD), plasma enhanced chemical vapor deposition (PECVD), atomic layer deposition (ALD), physical vapor deposition (PVD), sputtering, chemical solution deposition, plating, or any combination thereof. The adhesion liner 120 may include one or more thin layers of material suitable for the given application including, but not limited to, titanium (Ti), chromium (Cr), nickel (Ni), tungsten (W), or any combination thereof. The thickness of adhesion liner 120 may vary depending on the deposition process used, as well as the material employed. The metal layer 130 may include any electrically conductive materials that are suitable for patterning including, but not limited to, molybdenum (Mo), niobium (Nb), rhodium (Rh), ruthenium (Ru), tantalum (Ta), tungsten (Wo), or any combination thereof. In an embodiment, the metal layer 130 may include any electrically conductive materials having an electrical resistivity greater than that of copper (Cu). In an embodiment, the metal layer 130 may include any electrically conductive materials having a thermal conductivity less than that of copper (Cu). The thermal conductor layer 140 may include any materials that have a high thermal conductivity including, but not limited to, diamond-like carbon (DLC), aluminum nitride (AlN), beryllium oxide (BeO), aluminum oxide (AlOx), silicon carbide (SiC), and any combination thereof. In an embodiment, the thermal conductor layer 140 may include any materials that have a thermal conductivity greater than 20 Watts per meter Kelvin. In those embodiments where the material stack 150 includes the optional etch stop layer (not depicted), the etch stop layer may include any suitable etch stop materials including, but not limited to, aluminum oxide (AlO), aluminum nitride (AlN), hafnium oxide (HfO), tantalum oxide (TaO), zirconium oxide (ZrO), an oxygen-doped silicon carbide (ODC), or any combination thereof.

Next, the patterned mask 160 is formed on top of the material stack 150. By way of example, the patterned hard mask 160 may be formed as follows. A hard mask material (e.g., silicon nitride, titanium nitride, tantalum nitride, or any suitable inorganic metal-containing material) or an organic soft mask material (e.g., carbon, hydrogen, oxygen, and optionally nitrogen, fluorine, and silicon) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the thermal conductor layer 140 (or on top of the optional etch stop layer, if present) of the material stack 150. A photoresist material (not depicted) is then deposited onto the surface of the mask material. The photoresist material can be applied by any suitable techniques, including, but not limited to, coating or spin-on techniques. A photomask (not depicted) patterned with shapes defining the patterned structure to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the mask material. Dry etch techniques (for example, an anisotropic etch process, such as reactive ion etch) may be employed to selectively remove portions of the mask material to form the patterned mask 160. After formation of the patterned mask 160, the photoresist material may be stripped from the patterned mask 160 by ashing or other suitable processes. The resulting structure may be subjected to a wet clean.

FIG. 2 illustrates a cross-sectional view of semiconductor interconnect structure 100 of FIG. 1 after performing subsequent processing steps, in accordance with at least one embodiment of the present invention. In assembly of semiconductor interconnect structure 100 of FIG. 2, the material stack 150 is patterned using a subtractive manufacturing process to form a set of lower-level metal lines 210A-210G. This step may generally be referred to as the subtractive patterning or subtractive etching portion of the semi-damascene process.

Using the patterned mask 160, which acts as an etch match, the material stack 150 may be patterned to form the set lower-level metal lines 210A-210G by etching the exposed portions of the adhesion liner 120, metal layer 130, and thermal conductor layer 140 using a multi-step etching process including, but not limited to, reactive ion etching (RIE), ion beam etching (IBE), chemical wet etching, or any combination thereof. The resulting structure may be subjected to a wet clean. The etching of the material stack 150 can be controlled by a timed etching process as known by one of ordinary skill in the art, such that the etching process is terminated upon reaching the top surface of the substrate 110. Alternatively, the etching process can be terminated upon reaching the top surface of the adhesion liner 120.

The patterning of the material stack 150 further results in the formation of openings 220A-220F between the set of lower-level metal lines 210A-210G. As depicted by FIG. 2, the openings completely extend through the thermal conductor layer 140, the metal layer 130, and the adhesion liner 120, such that the openings 220A-220F expose the top surface the substrate 110. Alternatively (not depicted), the openings 220A-220F may extend to the top surface of the adhesion liner 120 if the etching process terminates thereon. It should be appreciated that the material stack 150 may be patterned to form any number of metal lines and openings, and that embodiments of the present invention are not limited to the particular number of metal lines and openings as depicted by FIG. 2.

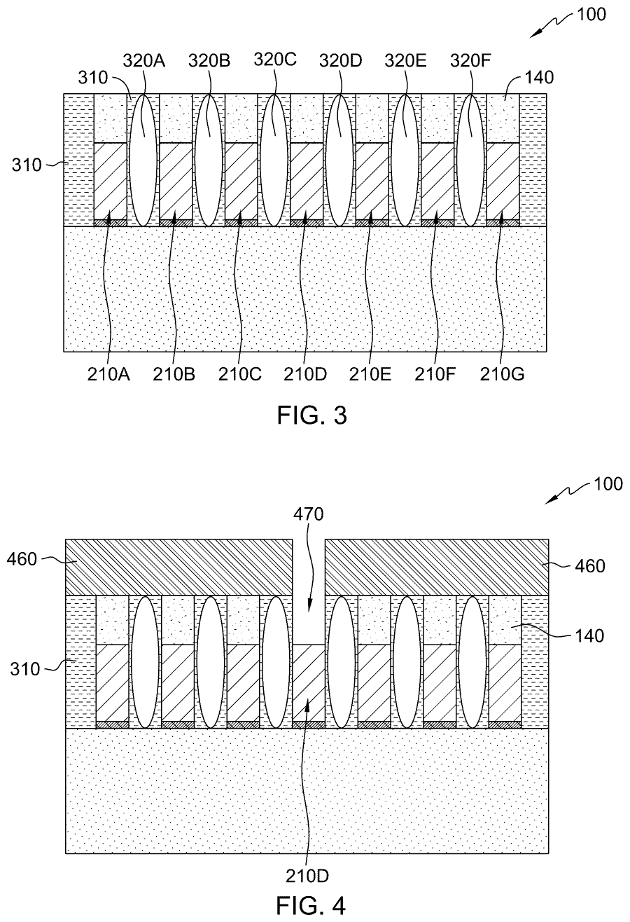

FIG. 3 illustrates a cross-sectional view of semiconductor interconnect structure 100 of FIG. 2 after performing subsequent processing steps, in accordance with at least one embodiment of the present invention. In assembly of semiconductor interconnect structure 100 of FIG. 3, the patterned mask 160 (depicted in FIG. 2) is removed, and the openings 220A-220F (depicted in FIG. 2) are backfilled with a dielectric material to form an interlayer dielectric (ILD) layer 310.

After removal of the patterned mask 160 (depicted in FIG. 2) using one or more processes as known by one of ordinary skill in the art, the dielectric material is deposited within the openings 220A-220F (depicted in FIG. 2) in a manner that results in the formation of air gaps 320A-320F in the dielectric material located between the set of lower-level metal lines 210A-210G.

The ILD layer 310 may be formed by depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Following the deposition of the dielectric material, a planarization process such as, for example, chemical mechanical planarization or polishing (CMP), and/or grinding, may be performed to remove portions of the ILD layer 310 located above the top surface of the thermal conductor layer 140. The planarization stops at the top surface of the thermal conductor layer 140, such that the top surface of the ILD layer 310 is substantially coplanar with the top surface thermal conductor layer 140.

The ILD layer 310 may be composed of an inorganic dielectric material or an organic dielectric material. Examples of suitable dielectric materials that may be employed as the ILD layer 310 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl. In some embodiments, the ILD layer 310 may have a dielectric constant (all dielectric constants mentioned herein are measured relative to a vacuum, unless otherwise stated) that is about 4.0 or less. In an embodiment, the ILD layer 310 may have a dielectric constant of 2.8 or less. Dielectric materials having a dielectric constant of 2.8 or less generally have a lower parasitic cross talk as compared to dielectric materials whose dielectric constant is greater than 4.0.

In various embodiments, a thermal conductivity of the thermal conductor layer 140 is greater than the thermal conductivity of the ILD layer 310. In some embodiments, the thermal conductivity of the thermal conductor layer is greater than 20 Watts per meter Kelvin and the thermal conductivity of the ILD layer 310 is less than 5 Watts per meter Kelvin.

As depicted by FIG. 3, the deposition of the dielectric material within the openings 220A-220F further results in the formation of air gaps 320A-320F within the dielectric material located between the lower-level metal lines 210A-210G. Due to the overhang phenomenon that occurs when an insulating film is simultaneously deposited on the entrance, sidewalls, or the bottom surface of an opening having a high aspect ratio, the top of the opening can be blocked before the opening is completely filled, generating air gaps inside the opening. Typically, air gaps will naturally occur when the aspect ratio of the area being filled is greater than 1 (and more frequently as the aspect ratio of the opening increases). In the instant case, since the openings 220A-220F (depicted in FIG. 2) have a high aspect ratio (i.e., the vertical dimensions of the openings are greater than the lateral dimensions of the openings), the air gaps 320A-320F will naturally form between the lower-level metal lines 210A-210G during the filling of the openings 220A-220F with the dielectric material. In alternative embodiments (not depicted), the dielectric material may be deposited in a manner that does not result in the formation of air gaps.

FIG. 4 illustrates a cross-sectional view of semiconductor interconnect structure 100 of FIG. 3 after performing subsequent processing steps, in accordance with at least one embodiment of the present invention. In assembly of semiconductor interconnect structure 100 of FIG. 4, a patterned mask 460 is formed, followed by the patterning of the thermal conductor layer 140 to form a via opening 470. It should be appreciated that the thermal conductor layer 140 may be patterned to form any number of via openings, and that embodiments of the present invention are not limited to the particular number of via openings as depicted by FIG. 4.

By way of example, the patterned mask 460 may be formed as follows. An inorganic hard mask material (e.g., silicon nitride, titanium nitride, tantalum nitride, or any suitable inorganic metal-containing material) or an organic soft mask material (e.g., carbon, hydrogen, oxygen, and optionally nitrogen, fluorine, and silicon) is deposited onto the top surfaces of the thermal conductor layer 140 and ILD layer 310, followed by the deposition of a photoresist material (not depicted) on top thereof using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. A photomask (not depicted) patterned with shapes defining the patterned structure to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the mask material. Dry etch techniques (for example, an anisotropic etch process, such as reactive ion etch) may be employed to selectively remove portions of the mask material to form the patterned mask 460. After formation of the patterned mask 460, the photoresist material may be stripped from the patterned mask 460 by ashing or other suitable processes. The resulting structure may be subjected to a wet clean.

Using the patterned mask 460, which acts as an etch match, the thermal conductor layer 140 may be patterned to form the via opening 470 by removing the physically exposed portions of the thermal conductor layer 140 using one or more etching processes including, but not limited to, reactive ion etching (RIE), ion beam etching (IBE), chemical wet etching, or any combination thereof. The resulting structure may be subjected to a wet clean. The etching of the thermal conductor layer 140 can be controlled by a timed etching process as known by one of ordinary skill in the art, such that the etching process is terminated upon reaching the top surface of the lower-level metal line 210D.

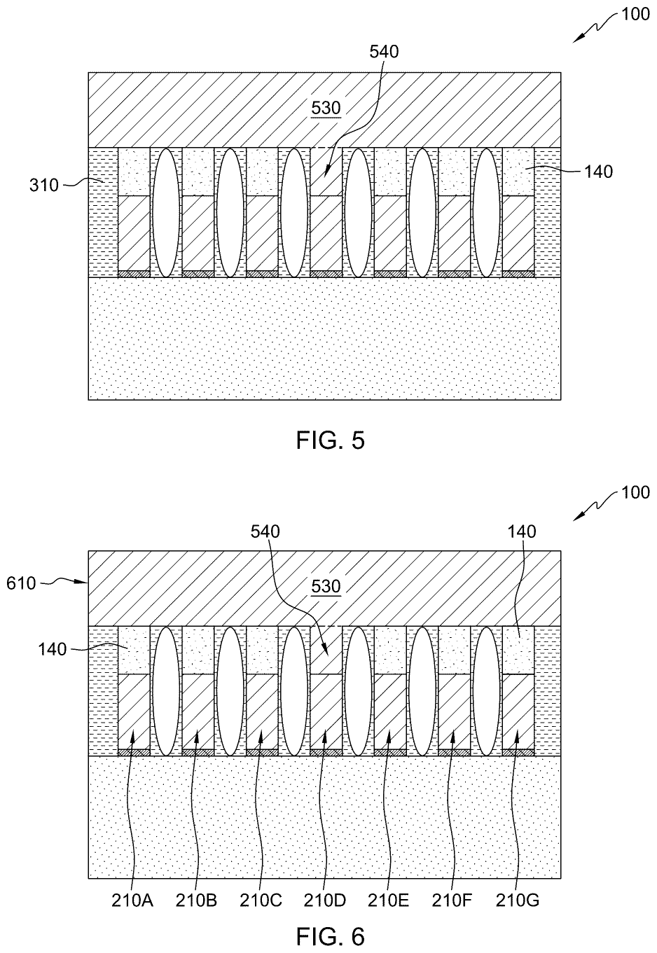

FIG. 5 illustrates a cross-sectional view of semiconductor interconnect structure 100 of FIG. 4 after performing subsequent processing steps, in accordance with at least one embodiment of the present invention. In assembly of semiconductor interconnect structure 100 of FIG. 5, a second metal layer 530 is formed by depositing an electrically conductive material within the via opening 470 (depicted in FIG. 4) and above the thermal conductor layer 140 and ILD layer 310, followed by a planarization process. The formation of the via opening 470 as described with respect to FIG. 4 and the filling of the via opening 470 with the electrically conductive material as described with respect to FIG. 5 may generally be referred to as the damascene portion of the semi-damascene process.

As depicted by FIG. 5, the filling of the via opening 470 (depicted in FIG. 4) with the electrically conductive material further results in the formation of a via 540 that is located above and in electrical contact with the lower-level metal line 210D. It should be noted that one or more additional vias (not depicted) may be formed, but that these other vias are not shown for clarity.

The second metal layer 530 may be formed by depositing an electrically conductive material within the via opening 470 (depicted in FIG. 4) and above the thermal conductor layer 140 and ILD layer 310 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The second metal layer 530 may include any electrically conductive materials that are suitable for patterning including, but not limited to, molybdenum (Mo), niobium (Nb), rhodium (Rh), ruthenium (Ru), tantalum (Ta), tungsten (Wo), or any combination thereof. In an embodiment, the second metal layer 530 may include any electrically conductive materials having a resistivity greater than that of copper (Cu). In an embodiment, the metal layer 530 may include any electrically conductive materials having a thermal conductivity less than that of copper (Cu). In an alternative embodiment, the metal layer 530 may include copper (Cu).

In some embodiments, depending on the particular electrically conductive materials used to form the metal layer 530, an optional diffusion barrier liner (not depicted) may be formed along the bottom and sidewall surfaces of the via opening 470 (depicted in FIG. 4) and along the top surfaces of the thermal conductor layer 140 and ILD layer 310 prior to depositing the electrically conductive material. The optional diffusion barrier liner is composed of a diffusion barrier material (i.e., a material that serves as a barrier to prevent the electrically conductive material used to form metal layer 540 from diffusing into the thermal conductor layer 140 and the ILD layer 310. The optional diffusion barrier liner may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

In some embodiments, and as depicted by FIG. 5, the metal layer 530 extends above the top surfaces of the thermal conductor layer 140 and the ILD layer 310. This is done to allow for the subsequent patterning of the metal layer 530 to form upper-level metal lines using a subtractive etching process as described in further detail with respect to FIG. 6. Thus, following the deposition of the electrically conductive material to form the metal layer 530, a planarization process such as, for example, chemical mechanical planarization or polishing (CMP), and/or grinding, may be performed to reduce the thickness of the metal layer 530 located above the top surfaces of the thermal conductor layer 140 and the ILD layer 310 to that of the desired thickness of the upper-level metal lines to be formed. The planarization stops at the top surface of the thermal conductor layer 140, such that the top surface of the ILD layer 310 is substantially coplanar with the top surface thermal conductor layer 140.

In alternative embodiments (not depicted), the metal layer 530 does not extend above the top surfaces of the thermal conductor layer 140 and the ILD layer 310. Rather, the metal layer 530 is only formed in the via opening 470 (depicted in FIG. 4), such that the metal layer 530 is substantially coplanar with the top surfaces of the thermal conductor layer 140 and the ILD layer 310. This is done to allow for the subsequent formation of the set of upper metal lines, including upper-level metal line 610 depicted in FIG. 6, using a damascene process.

For example, after filling the via opening 470 (depicted in FIG. 4) with an electrically conductive material to form the via 540, a dielectric material is deposited onto the top surfaces of the thermal conductive layer 140, ILD layer 310, and via 540 to form an interlayer dielectric layer (ILD). The set of upper-level metal lines, including upper-level metal line 610 depicted in FIG. 6, may be formed within the ILD layer using a damascene process as known by one of ordinary skill in the art, and as such, a more detailed description of such process is not presented herein.

FIG. 6 illustrates a cross-sectional view of semiconductor interconnect structure 100 of FIG. 5 after performing subsequent processing steps, in accordance with at least one embodiment of the present invention. In assembly of semiconductor interconnect structure 100 of FIG. 6, the portion of the metal layer 530 formed above the top surfaces of the thermal conductor layer 140 and the ILD layer 130 is patterned using a subtractive manufacturing process to form a set of upper-level metal lines. It should be noted that only one upper-level metal line 610 in the set of upper-level lines has been depicted for clarity purposes, and that the set of upper-level metal lines may include any number of metal lines in addition to the upper-level metal line 610.

The set of upper-level metal lines may be formed by initially forming a patterned mask (not depicted) above the metal layer 530 using the same processes and materials as previously described with respect to the formation of the patterned mask 460 (depicted in FIG. 4). Then, using the patterned mask, which acts as an etch match, the metal layer 530 may be patterned to form the set of upper-level metal lines by etching the exposed portions of the metal layer 530 using an etching process including, but not limited to, reactive ion etching (RIE), ion beam etching (IBE), chemical wet etching, or any combination thereof. The resulting structure may be subjected to a wet clean. The etching of the metal layer 530 can be controlled by a timed etching process as known by one of ordinary skill in the art, such that the etching process is terminated upon reaching the top surface of the ILD layer 310.

In some embodiments, and as depicted by FIG. 6, the metal layer 130 used to form the set of lower-level metal lines 210A-210G and the metal layer 530 used to form the set of upper-level metal lines (including upper level-metal line 610) are formed from the same electrically conductive material. However, in other embodiments (not depicted), the metal layer 130 used to form the set of lower-level metal lines 210A-210G and the metal layer 530 used to form the set of upper-level metal lines (including upper level-metal line 610) may be formed from different electrically conductive materials.

As can be appreciated by the semiconductor interconnect structure 100 depicted by FIG. 6, the thermal conductor layer 140 is formed within the via level located above the set of lower-level metal lines 210A-210G. By substituting what is typically an interlayer dielectric material having a low thermal conductivity for a highly conductive thermal dielectric material in the areas of the via level located above the set of lower-level metal lines 210A-210G, a thermal path for heat transport is created from one metal level to the next. This is particularly advantageous when the lower-level BEOL interconnect layers are formed using a semi-damascene process, since this process poses a challenge to heat dissipation due to the formation of thermally insulating air gaps within the interlayer dielectric and the use of lower thermally conductive materials as compared to copper.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure.

However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A semiconductor interconnect structure, comprising:
a set of lower-level metal lines, the set of lower-level metal lines formed by subtractive etching;
a thermal conductive layer formed above the set of lower-level metal lines;
an interlayer dielectric layer surrounding sidewalls of the set of lower-level metal lines and the thermal conductive layer formed above the set of lower-level metal lines;
a via formed above a first metal line in the set of lower-level metal lines; and
a set of upper-level metal lines formed above the thermal conductive layer,
wherein a thermal conductivity of the thermal conductive layer is greater than a thermal conductivity of the interlayer dielectric layer.

2. The semiconductor interconnect structure of claim 1, further comprising air gaps formed within the interlayer dielectric layer, the air gaps being located between adjacent metal lines in the set of lower-level metal lines.

3. The semiconductor interconnect structure of claim 1, wherein the interlayer dielectric layer surrounds sidewalls of the via.

4. The semiconductor interconnect structure of claim 1, wherein the via is formed using a damascene process.

5. The semiconductor interconnect structure of claim 1, wherein the set of lower-level metal lines and the set of upper-level metal lines are formed from the same electrically conductive material.

6. The semiconductor interconnect structure of claim 1, wherein the set of lower-level metal lines and the set of upper-level metals lines are formed from different electrically conductive materials.

7. The semiconductor interconnect structure of claim 1, wherein the set of lower-level metal lines are formed from an electrically conductive material having an electrical resistivity that is greater than that of copper.

8. The semiconductor interconnect structure of claim 1, wherein the set of lower-level metal lines are formed from an electrically conductive material having a thermal conductivity that is less than that of copper.

9. The semiconductor interconnect structure of claim 1, wherein the set of lower-level metal lines and the set of upper-level metal lines are formed from an electrically conductive material selected from the group consisting of: molybdenum (Mo), niobium (Nb), rhodium (Rh), ruthenium (Ru), tantalum (Ta), tungsten (Wo), and any combination thereof.

10. The semiconductor interconnect structure of claim 1, wherein the thermal conductive layer is formed from a dielectric material selected from the group consisting of: diamond-like carbon (DLC), aluminum nitride, a beryllium oxide (BeO), aluminum oxide (AlOx), silicon carbide (SiC), and any combination thereof.

11. The semiconductor interconnect structure of claim 1, wherein a thermal conductivity of the thermal conductive layer is greater than 20 Watts per meter Kelvin.

12. A method of forming a semiconductor interconnect structure, comprising:
forming a set of lower-level metal lines, the set of lower-level metal lines formed by subtractive etching;
forming a thermal conductive layer above the set of lower-level metal lines;
forming an interlayer dielectric layer, wherein the interlayer dielectric layer surrounds sidewalls of the set of lower-level metal lines and the thermal conductive layer formed above the set of lower-level metal lines;
forming a via above a first metal line in the set of lower-level metal lines;
forming a set of upper-level metal lines above the thermal conductive layer,
wherein a thermal conductivity of the thermal conductive layer is greater than a thermal conductivity of the interlayer dielectric layer.

13. The method of claim 12, further comprising:
forming a material stack, the material stack including a metal layer and the thermal conductive layer formed above the metal layer; and
subtractively etching the material stack to form the set of lower-level metal lines and the thermal conductive layer above the set of lower-level metal lines.

14. The method of claim 12, wherein forming the via comprises:
forming a via opening by removing a portion of the thermal conductive layer formed above the first metal line in the set of lower-level metal lines; and
filling the via opening with an electrically conductive material.

15. The method of claim 12, further comprising forming air gaps within the interlayer dielectric layer, the air gaps being located between adjacent metal lines in the set of lower-level metal lines.

16. The method of claim 13, wherein the interlayer dielectric layer surrounds the sidewalls of the via.

17. The method of claim 12, wherein the set of lower-level metal lines and the set of upper-level metal lines are formed from an electrically conductive material having an electrical resistivity that is greater than that of copper.

18. The method of claim 12, wherein the set of lower-level metal lines and the set of upper-level metal lines comprise an electrically conductive material having a thermal conductivity that is less than that of copper.

19. The method of claim 12, wherein the set of lower-level metal lines and the set of upper-level metal lines are formed from an electrically conductive material selected from the group consisting of: molybdenum (Mo), niobium (Nb), rhodium (Rh), ruthenium (Ru), tantalum (Ta), tungsten (Wo), and any combination thereof.

20. The method of claim 12, wherein the thermal conductive layer is formed from a dielectric material selected from the group consisting of: diamond-like carbon (DLC), aluminum nitride (AlN), beryllium oxide (BeO), aluminum oxide (AlOx), silicon carbide (SiC), and any combination thereof.
